(19) United States
(12) Patent Application Publication
(10) Pub. No.: US 2002/0047789 A1
(43) Pub. Date: Apr. 25, 2002

(54) Method of designing semiconductor integrated circuit

(76) Inventors: Yasuhiko Inada, Kawasaki (JP); Daisuke Miura, Kawasaki (JP); Masayuki Okamoto, Kawasaki (JP); Mitsuaki Nagasaka, Kawasaki (JP); Toshio Arakawa, Kawasaki (JP)

Correspondence Address: STAAS & HALSEY LLP, 700 11TH STREET, NW, SUITE 500, WASHINGTON, DC, 20001, US

(21) Appl. No.: 09/788,403

(22) Filed: Feb. 21, 2001

(30) Foreign Application Priority Data
May 24, 2000 (JP) 2000-153695

(51) Int. Cl. H03M 9/00

(52) U.S. Cl. 341/100

(57) ABSTRACT

A method of designing a semiconductor integrated circuit includes the steps of generating a cell that includes a flip-flop and backup transistors, designing a circuit by use of the cell, and adjusting a timing by connecting the backup transistors to the flip-flop if there is a need to adjust timing of the flip-flop.

### BACKGROUND OF THE INVENTION

1. Field of the Invention

The present invention generally relates to a method of designing semiconductor integrated circuits, and particularly relates to a method of designing a semiconductor integrated circuit while adjusting timings.

2. Description of the Related Art

Conventional logic designing attends to a timing check after layout designing. If the timing check finds errors, changes are made to logic circuits and layouts around a flip-flop that has exhibited a timing error. A timing check is made again after the change of the layout. If further errors are found in this timing check, further changes are made to logic circuits and layouts around a faulty flip-flop. Timing checks and layout changes are repeated in this manner so as to settle the logic circuit design such that there are no more errors.

In such a method, when cells are added for the purpose of correcting a timing-error flip-flop portion, for example, the added cells may be located spatially far away from the flip-flop, or the connecting wires may need to make a detour. In such a case, settling the circuit design is a difficult task. Further, a layout change caused by a change in the circuit design may result in another timing error at another circuit portion. This increases the number of timing checks and layout changes to be carried out, resulting in a lengthy time for the circuit design.

Accordingly, there is a need for a method of designing semiconductor integrated circuits that can shorten a time period required for designing a circuit including sequential logic.

### SUMMARY OF THE INVENTION

It is a general object of the present invention to provide a method of designing semiconductor integrated circuits that substantially obviates one or more of the problems caused by the limitations and disadvantages of the related art.

Features and advantages of the present invention will be set forth in the description which follows, and in part will become apparent from the description and the accompanying drawings, or may be learned by practice of the invention according to the teachings provided in the description. Objects as well as other features and advantages of the present invention will be realized and attained by the method particularly pointed out in the specification in such full, clear, concise, and exact terms as to enable a person having ordinary skill in the art to practice the invention.

To achieve these and other advantages and in accordance with the purpose of the invention, as embodied and broadly described herein, the invention provides a method of designing a semiconductor integrated circuit, including the steps of a) generating a cell that includes a flip-flop and backup transistors, b) designing a circuit by use of the cell, and c) adjusting a timing by connecting the backup transistors to the flip-flop if there is a need to adjust timing of the flip-flop.

In the method as described above, backup transistors are provided in a cell area of the flip-flop, and are used for the purpose of timing adjustment inside the cell when a timing check after designing of a layout finds timing errors. Because of this, wire changes are confined within the cell, so that timing adjustment can be achieved without affecting timings of other circuits. Further, since the wires for the timing adjustment can be relatively short to serve their purpose, it is easy to settle the logic design. Moreover, since correction can all be made within the wiring layer, there is no need to redesign layouts in layers below the wiring layer.

According to another aspect of the present invention, the method as described above further includes the steps of generating flip-flop variations having different signal timings by connecting the backup transistors to the flip-flop, extracting cell characteristics with respect to the flip-flop variations, and storing cells of the flip-flop variations together with the cell characteristics as a library.

Further, in the method as described above, the step c) includes the steps of retrieving from the library a cell with a proper timing in respect of a cell in need of timing adjustment by taking into account the cell characteristics, and replacing the cell in need of timing adjustment with the retrieved cell so as to attend to timing adjustment.

The library created in this manner is provided with flip-flops having various timings and driving powers. Since cell characteristics of these flip-flops are known, capacitance and resistance values of wires can be taken into account to provide accurate timing. When timing errors are detected at the time of timing checks, therefore, a flip-flop cell having desired timing and/or desired driving power is retrieved from the library, and replaces the cell that has timing errors. This makes it possible to provide desired timing relations without affecting other cells.

### BRIEF DESCRIPTION OF THE DRAWINGS

FIGS. 1A and 1B are illustrative drawing for explaining the principle of the present invention;

FIG. 2 is a flowchart of a process of creating a library of flip-flops;

FIG. 3 is a flowchart showing a method of designing a semiconductor integrated circuit by use of the library according to the present invention;

FIGS. 4A and 4B are drawings showing an example of a flip-flop stored in the library according to the present invention;

FIGS. 5A and 5B are drawings showing an example of a flip-flop stored in the library according to the present invention;

FIGS. 6A and 6B are drawings showing an example of a flip-flop stored in the library according to the present invention;

FIG. 7 is a drawing showing an example of a flip-flop stored in the library according to the present invention;

FIG. 8 is a drawing showing an example of a flip-flop stored in the library according to the present invention;

FIG. 9 is a drawing showing an example of use of transistors that are not used in the flip-flop of FIG. 7; and

FIGS. 10A and 10B are drawings for explaining the effectiveness of the design method according to the present invention.

### DESCRIPTION OF THE PREFERRED EMBODIMENTS

In the following, embodiments of the present invention will be described with reference to the accompanying drawings.

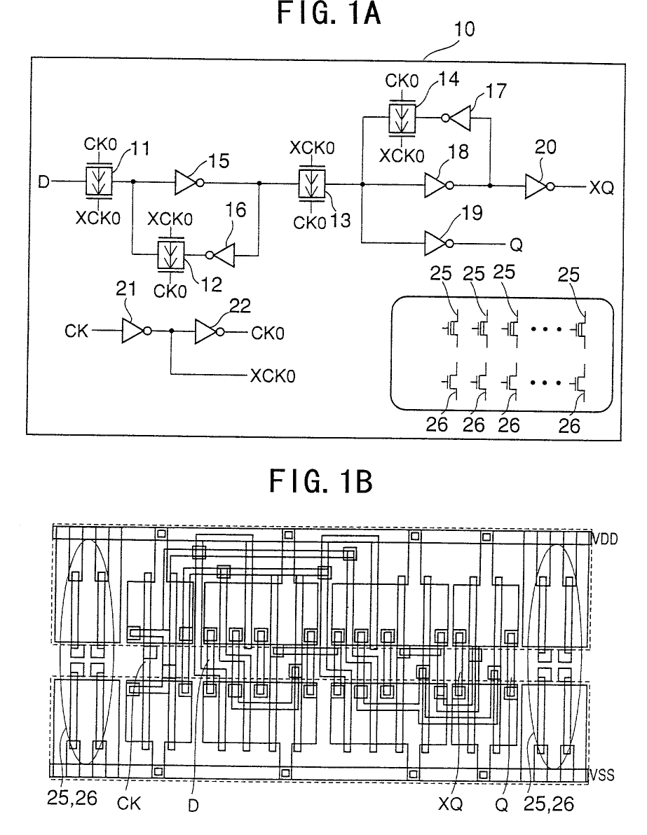

FIGS. 1A and 1B are illustrative drawing for explaining the principle of the present invention.

FIG. 1A shows a circuit diagram of a master-slave flip-flop, and FIG. 1B shows a layout of the flip-flop of FIG. 1A.

The flip-flop shown in FIG. 1A includes transfer gates 11 through 14 and inverters 15 through 22. The inverters 21 and 22 together form a circuit that generates complementary clock signals CK0 and XCK0 from a clock signal CK. The clock signals CK0 and XCK0 are supplied to the transfer gates 11 through 14. As shown in FIG. 1A, according to the present invention, a plurality of PMOS transistors 25 and a plurality of NMOS transistors 26 are provided as backup transistors within a cell area 10 of the flip-flop. The backup transistors 25 and 26 will be used for the purpose of timing adjustment when a timing check finds errors.

As shown in the layout diagram of FIG. 1A, the plurality of PMOS transistors 25 and the plurality of NMOS transistors 26 are located close to an input node D of the flip-flop or output nodes Q and XQ of the flip-flop.

In the present invention as described above, backup transistors are provided in a cell area of the flip-flop, and are used for the purpose of timing adjustment inside the cell when a timing check after designing of a layout finds timing errors. Because of this, wire changes are confined within the cell, so that timing adjustment can be achieved without affecting timings of other circuits. Further, since the wires for the timing adjustment can be relatively short to serve their purpose, it is easy to settle the logic design. Moreover, since correction can all be made within the wiring layer, there is no need to redesign layouts in layers below the wiring layer. This results in a shorter time period for layout redesign, and a manufacturing processing can be started while carrying out the timing checks.

According to the present invention, as will be described below, various flip-flops having different timings are constructed by use of the backup transistors 25 and 26, and are provided as a library. This makes it possible to solve timing errors at once after a single timing check.

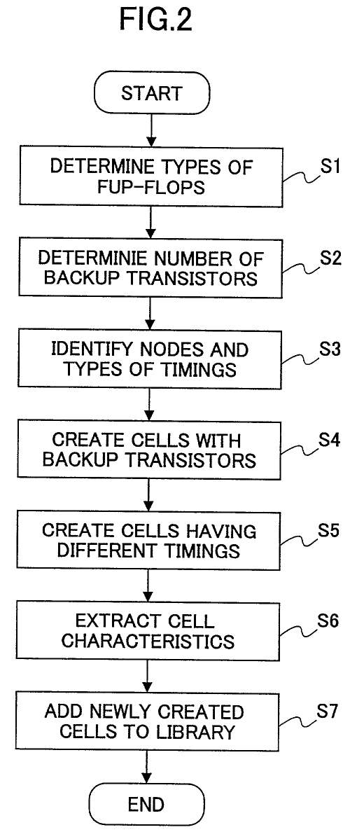

FIG. 2 is a flowchart of a process of creating a library of flip-flops.

At a step S1, types of flip-flops that are to be included in a library are determined. For example, a library is to be created with respect to two types of flip-flops FF1 and FF2.

At a step S2, the number of backup transistors to be placed within the flip-flop cell is determined. In detail, the number of necessary transistors is determined by taking into consideration a size of a timing displacement that needs to be resolved by a fine timing adjustment. The fine timing adjustment is performed after a CAD tool for designing a semiconductor integrated circuit carries out automatic timing adjustment, and is necessary because such an automatic timing adjustment can resolve timing errors only with a limited accuracy. If a timing displacement X needs to be resolved by a fine timing adjustment after an automatic timing adjustment by the CAD tool, and a delay of each backup transistor is Y, then, the backup transistors need to be provided as many as X/Y, more or less.

At a step S3, nodes that may need timing adjustment are identified for each flip-flop, and types of timings that need to be added to these nodes are determined. For example, FF1 may have the nodes D, CK, and Q that may need timing adjustment, and a logic design pattern having two types of different timings (or driving powers) is generated for each node. FF2 may have the nodes D, CK, Q, and XQ that may need timing adjustment. For FF2, an additional logic design pattern having a new timing (or driving power) is generated with respect to the nodes D and Q, and a logic design pattern having three different timings is generated with respect to the node CK, with a further logic design pattern being generated for the node XQ to provide two different driving powers.

At a step S4, a cell layout is created for each flip-flop cell such as to provide backup transistors as many as decided at the step S2. In detail, the layout is determined such that the backup transistors are provided close to the nodes identified at the step S3. Further, the layout is determined such that the backup transistors and these nodes are connectable by use of a wiring layer alone, i.e., by use of metal wires and a contact layer. The flip-flop cells created at the step S4 and having the backup transistors are denoted as FF1_TR.

At a step S5, layouts are created based on the flip-flops created at the step S4 to provide different timings for each node identified at the step S3 by use of the backup transistors. As a result, cell layouts having different timings for each node are created.

For example, a cell FF1_TR_D1 is created by attaching a delay to the node D of the flip-flop FF1_TR that is created at the step S4, and, also, a cell FF1_TR_D2 having a different delay is created. By the same token, a cell FF1_TR_CK1 is created by adding a delay to the node CK of the flip-flop FF1_TR that is created at the step S4. Also, a cell FF1_TR_CK2 having a different delay is created. Further, changes are made to the driving power of the node Q of the flip-flop FF1_TR, thereby creating cells FF1_TR_Q1 and FF1_TR_Q2.

In the same manner, a plurality of different cells are created for FF2, resulting in FF2_TR_D, FF2_TR_CK1, FF2_TR_CK2, FF2_TR_CK3, FF2_TR_Q, FF2_TR_XQ1, and FF2_TR_XQ2.

At a step S6, cell characteristics (resistance and capacitance of each wire) are identified in respect of the cells created at the step S5.

At a step S7, the newly created cells are added to the library. As a result, the library includes:

FF1 (originally included in the library);

FF1_TR (with an added backup transistor);

FF1_TR_D1 (with a different timing for the node D);

FF1_TR D2 (with a different timing for the node D);

FF1_TR_CK1 (with a different timing for the node CK);

FF1_TR_CK2 (with a different timing for the node CK);

FF1_TR_Q1 (with a different driving power for the node Q);

FF1TR_Q2 (with a different driving power for the node Q);

FF2 (originally included in the library);

FF2_TR (with an added backup transistor);

FF2_TR_D (with a different timing for the node D);

FF2_TR_CK1 (with a different timing for the node CK);

FF2_TR_CK2 (with a different timing for the node CK);

FF2_TR_CK3 (with a different timing for the node CK);

FF2_TR_Q (with a different driving power for the node Q);

FF2_TR_XQ1 (with a different driving power for the node XQ); and

FF2_{—TR_XQ2 (with a different driving power for the node XQ).}

The library created in this manner is provided with flip-flops having various timings and driving powers. Since cell characteristics of these flip-flops are known, capacitance and resistance values of wires can be taken into account to provide accurate timing. When timing errors are detected at the time of timing checks as part of a designing process of semiconductor integrated circuits, therefore, a flip-flop cell having desired timing and/or desired driving power is retrieved from the library, and replaces the cell that has timing errors. This makes it possible to provide desired timing relations without affecting other cells.

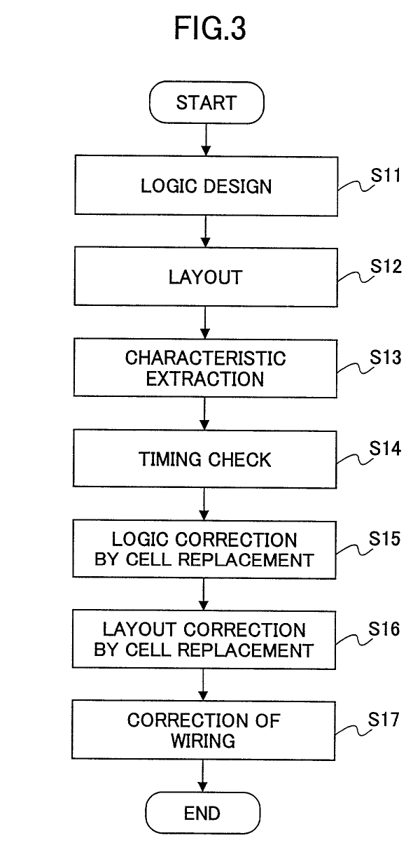

FIG. 3 is a flowchart showing a method of designing a semiconductor integrated circuit by use of the library according to the present invention.

At a step S11, a logic design of a semiconductor integrated circuit is determined.

At a step S12, a layout design of a semiconductor integrated circuit is determined.

At a step S13, circuit characteristics such as resistance and capacitance of wires are extracted.

At a step S14, timing checks are carried out.

At a step S15, a cell included in the library and having a proper timing is used in the logic design to replace the cell that has a timing error detected by the timing checks. After this, a logic check that takes into account the cell characteristics is made, thereby making sure that there is no timing error.

At a step S16, the cell that is provided as the logic replacement at the step S15 is used as a layout replacement.

At a step S17, wire layouts are corrected with respect to the cell that is provided as the replacement. The procedure then comes to an end.

According to the present invention as described above, the timing check and the layout correction are not repeated, and are performed only once to complete the design process. This is because desired timing relations can be achieved without affecting other cells by replacing a cell having a timing error with a flip-flop cell retrieved from the library where the flip-flop cell has a proper timing and a proper driving power and is retried from the library including a number of flip-flops whose cell characteristics are already known.

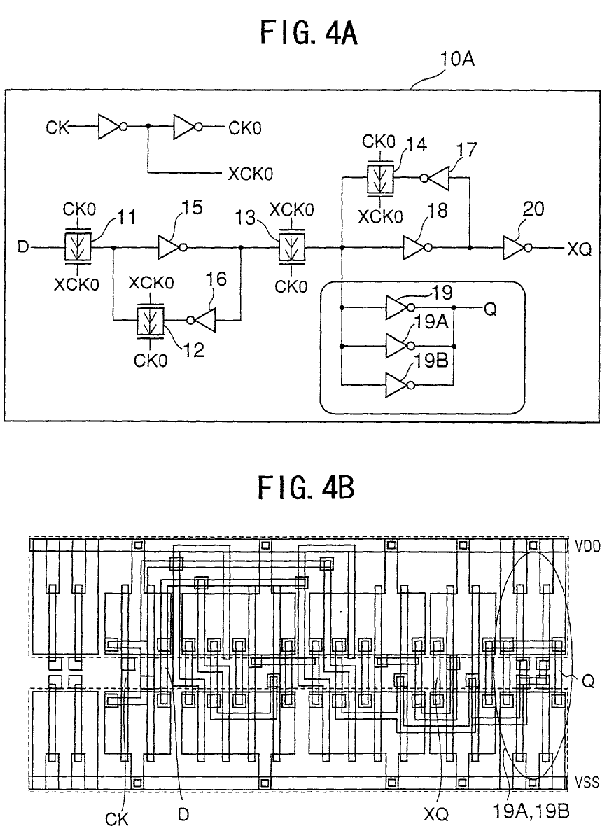

FIGS. 4A and 4B are drawings showing an example of a flip-flop stored in the library according to the present invention. A flip-flop shown in FIGS. 4A and 4B is stored in the library as a variation of the flip-flop shown in FIG. 1. In FIGS. 4A and 4B, the same elements as those of FIG. 1 are referred to by the same numerals, and a description thereof will be omitted.

FIG. 4A shows a circuit diagram of a master-slave flip-flop, and FIG. 4B shows a layout of the flip-flop of FIG. 4A.

In a cell area 10A of the flip-flop shown in FIG. 4A, inverters 19A and 19B are provided that are configured by using the backup transistors 25 and 26 shown in FIG. 1A, and are connected in parallel to the output node Q. This enhances the driving power of the output node Q, thereby reducing the delay time of data. As can be seen from FIG. 1B and FIG. 4B, the inverters 19A and 19B are created by using the backup transistors 25 and 26 that are positioned close to the output node Q shown in FIG. 1B. This makes it possible to enhance the driving power of the output node Q without having other cells and other portions of the same cell affected by the wire layout changes.

In order to improve the driving power of the output node Q, the inverters 19A and 19B may not have to be connected to the output node Q. As an alternative, the output node Q is used as a first output node, and the output nodes of the inverters 19A and 19B may be used as second and third output nodes. Such a configuration can decrease a fanout by distributing the load connected to the flip-flop, and can thus shorten the delay time of data.

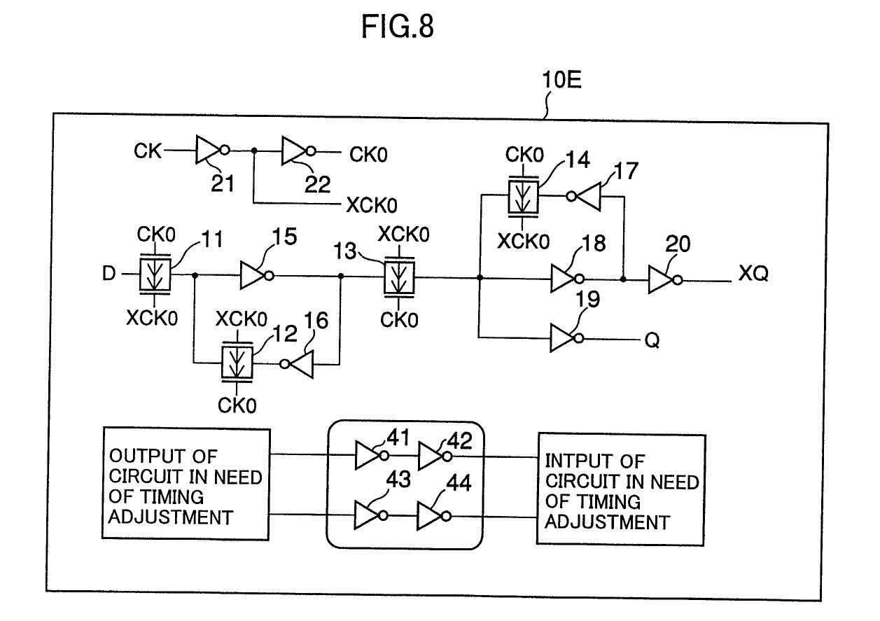

As will be described later with reference to FIG. 8, when the backup transistors 25 and 26 are used up in the flip-flop cell area 10A, and there is a need for a further timing adjustment, backup transistors of a neighboring flip-flop cell may be used. Namely, the backup transistors of a neighboring flip-flop cell are employed to attach inverters in parallel to the output node of the cell 10A.

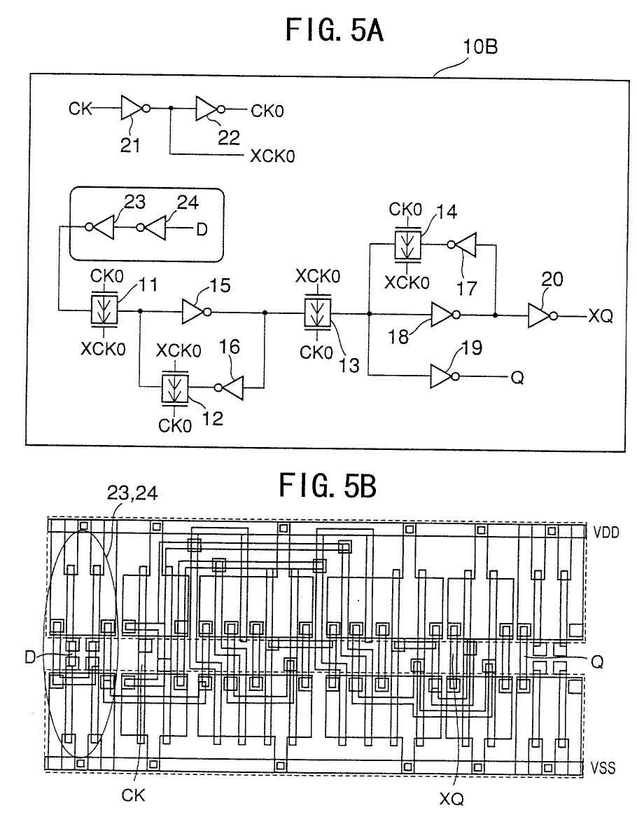

FIGS. 5A and 5B are drawings showing an example of a flip-flop stored in the library according to the present invention. A flip-flop shown in FIGS. 5A and 5B is stored in the library as a variation of the flip-flop shown in FIG. 1. In FIGS. 5A and 5B, the same elements as those of FIG. 1 are referred to by the same numerals, and a description thereof will be omitted.

In a cell area 10B of the flip-flop shown in FIG. 5A, inverters 23 and 24 are provided that are configured by using the backup transistors 25 and 26 shown in FIG. 1A, and are connected in series to the input node D. This makes it possible to adjust data timing of the data that is input to the flip-flop at the input node D. As can be seen from FIG. 1B and FIG. 5B, the inverters 23 and 24 are created by using the backup transistors 25 and 26 that are positioned close to the input node D shown in FIG. 1B. This makes it possible to adjust timing without having other cells and other portions of the same cell affected by the wire layout changes, and all of this is achieved by making changes to the wiring layer alone.

When the backup transistors 25 and 26 are used up in the flip-flop cell area 10B, and there is a need for a further timing adjustment, backup transistors of a neighboring flip-flop cell may be used.

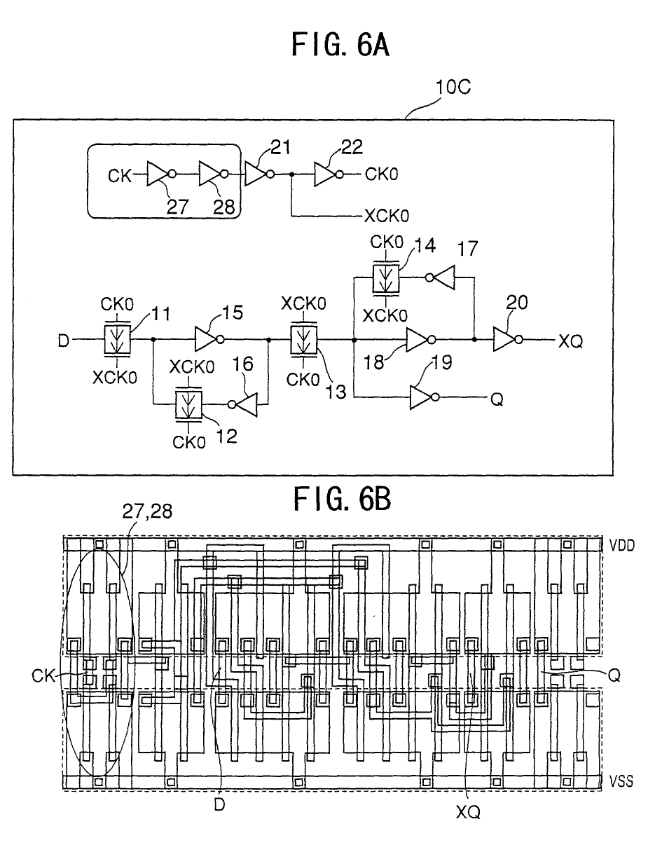

FIGS. 6A and 6B are drawings showing an example of a flip-flop stored in the library according to the present invention. In FIGS. 6A and 6B, the same elements as those of FIG. 1 are referred to by the same numerals, and a description thereof will be omitted.

In a cell area 10C of the flip-flop shown in FIG. 6A, inverters 27 and 28 are provided that are configured by using the backup transistors 25 and 26 shown in FIG. 1A, and are connected in series to the input node for the clock signal CK. This makes it possible to adjust timing of the clock signal CK. As can be seen from FIG. 1B and FIG. 6B, the inverters 27 and 28 are created by using the backup transistors 25 and 26 that are positioned close to the clock-signal input node CK shown in FIG. 1B. This makes it possible to adjust timing without having other cells and other portions of the same cell affected by the wire layout changes, and all of this is achieved by making changes to the wiring layer alone.

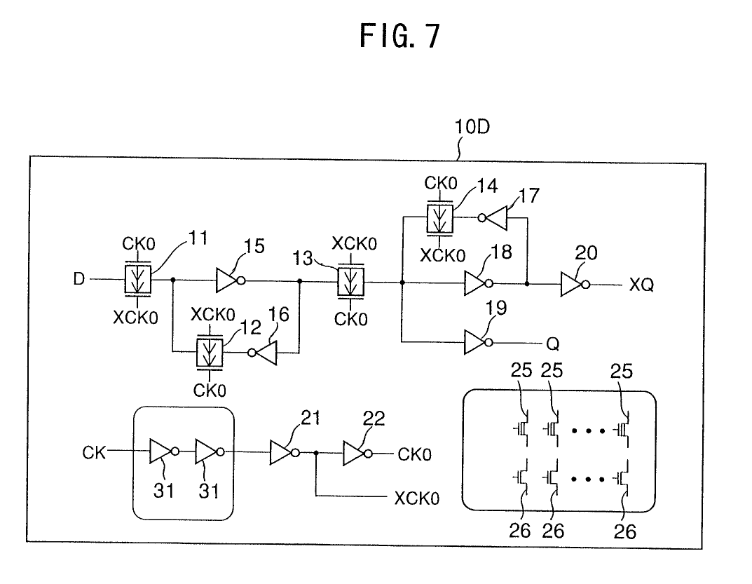

FIG. 7 is a drawing showing an example of a flip-flop stored in the library according to the present invention. In FIG. 7, the same elements as those of FIG. 1 are referred to by the same numerals, and a description thereof will be omitted.

In a cell area 10D of the flip-flop shown in FIG. 7, inverters 31 and 32 are provided as part of the original configuration in addition to the backup transistors 25 and 26, and are connected in series to the clock input node. In comparison with the flip-flop shown in FIG. 1A, the timing of the clock signal CK becomes delayed. The cell of FIG. 7 is used in place of the cell 10 of FIG. 1 at the initial stage of the logic design process. With the inverters 31 and 32 in their place, timing is adjustable in such a direction as to reduce the delay by removing these existing inverters.

Transistors that are provided for the purpose of adjusting timing in such a direction as to reduce the delay are not limited to the input node for the clock signal, but can be provided at any positions such as an output node of the flip-flop.

FIG. 8 is a drawing showing an example of a flip-flop stored in the library according to the present invention. In FIG. 8, the same elements as those of FIG. 1 are referred to by the same numerals, and a description thereof will be omitted.

In a cell area 10E of the flip-flop shown in FIG. 8, the inverters 41 through 44 are configured by using the backup transistors 25 and 26 shown in FIG. 1A, and are provided for use by neighboring cells of the cell area 10E when there is a need for timing adjustment. In this case, wiring corrections that cross the cell border become necessary. Since the inverters provided as part of the original configuration of the 10E will be used, however, there is no need to add new cells, so that wiring changes to the wiring layer alone is all that is necessary.

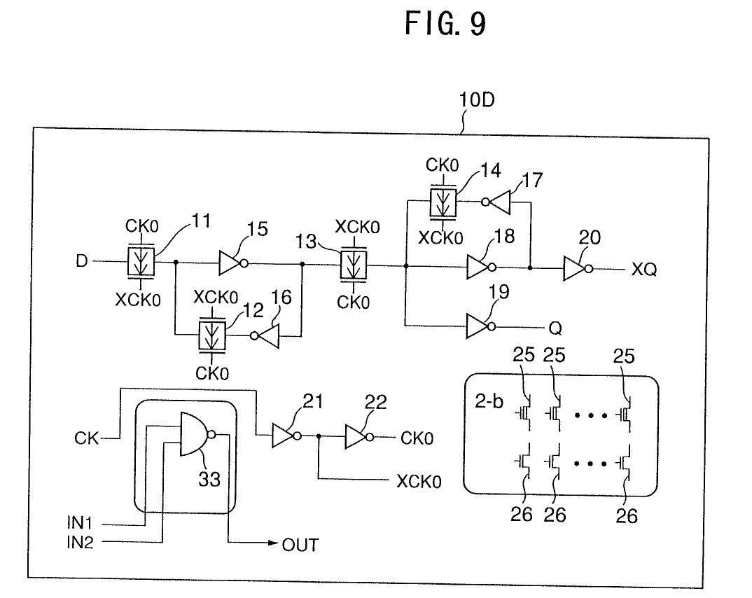

FIG. 9 is a drawing showing an example of use of transistors that are not used in the flip-flop of FIG. 7. In FIG. 9, the same elements as those of FIG. 7 are referred to by the same numerals, and a description thereof will be omitted.

In FIG. 9, a NAND circuit 33 provided in the cell 10D is a logic device that is configured by use of the transistors that were used in FIG. 7 to make up the inverters 31 and 32. The NAND circuit 33 is usable as an additional circuit element or a timing adjustment circuit portion to be used by a neighboring cell of the cell 10D. When a timing check finds a timing error in the flip-flop cell of FIG. 7 after using the cell for logic design, the inverters 31 and 32 may become unnecessary as a result of timing adjustment. In such a case, the transistors that would have made up the inverters 31 and 32 may be utilized and provided for use by a neighboring cell if this neighboring cell needs transistors.

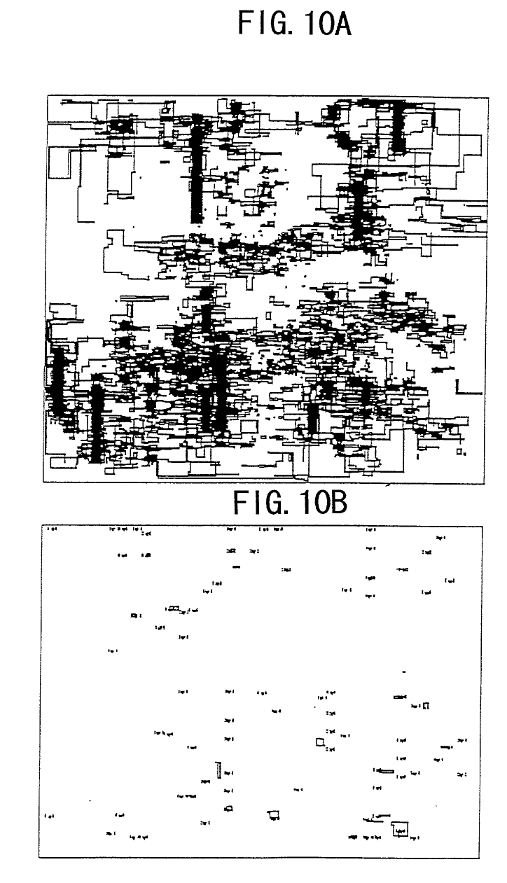

FIGS. 10A and 10B are drawings for explaining the effectiveness of the design method according to the present invention.

FIGS. 10A and 10B show how much a layout is corrected as a result of a timing check and a timing adjustment that are performed once when a semiconductor integrated circuit macro is designed as an example. FIG. 10A shows portions that are subjected to layout changes when a conventional method of changing a layout is used. When a change is made to ad or remove a straight line wire, for example, a straight line would be shown in the figure as an indication of the change of the wiring layout. When a cell is added or removed, for example, a dot proportional to the size of the cell would be shown in the drawing. FIG. 10B shows portions that are subjected to layout changes when the library of the present invention is used to change the layout. FIGS. 10A and 10B show portions that are corrected as a result of a single round of a timing check and a timing adjustment, and do not show a case in which the timing check and the layout correction are repeated multiple times.

As can be seen from the comparison of FIG. 10A with FIG. 10B, use of the designing method of the present invention results in a drastically smaller number of layout corrections compared to when the conventional designing method is used. This is because a layout correction for adjusting timing of a given cell does not affect other cells, and, also, is because no excessive correction is made to the cell that is subjected to the timing adjustment.

Further, the present invention is not limited to these embodiments, but various variations and modifications may be made without departing from the scope of the present invention.

The present application is based on Japanese priority application No. 2000-153695 filed on May 24, 2000, with the Japanese Patent Office, the entire contents of which are hereby incorporated by reference.

What is claimed is:

1. A method of designing a semiconductor integrated circuit, comprising the steps of:
a) generating a cell that includes a flip-flop and backup transistors;
b) designing a circuit by use of the cell; and
c) adjusting a timing by connecting the backup transistors to the flip-flop if there is a need to adjust timing of the flip-flop.

2. The method as claimed in claim 1, further comprising the steps of:
generating flip-flop variations having different signal timings by connecting the backup transistors to the flip-flop;
extracting cell characteristics with respect to the flip-flop variations; and
storing cells of the flip-flop variations together with the cell characteristics as a library.

3. The method as claimed in claim 2, wherein said step c) includes the steps of:
retrieving from the library a cell with a proper timing in respect of a cell in need of timing adjustment by taking into account the cell characteristics; and
replacing the cell in need of timing adjustment with the retrieved cell so as to attend to timing adjustment.

4. The method as claimed in claim 1, wherein said step a) includes a step of laying out such that the flip-flop and the backup transistors are connectable through a wiring layer and no other layers.

5. The method as claimed in claim 1, wherein said step a) further includes a step of determining a number of the backup transistors based on a range of timing adjustment that is necessary after initial timing adjustment in which a timing adjustable by a CAD system is adjusted.

6. The method as claimed in claim 1, further comprising a step of attaching available backup transistors of a neighboring cell to a cell having no available backup transistors so as to adjust timing if there is a need to adjust timing of the cell having no available backup transistors.

7. The method as claimed in claim 1, wherein said step a) includes a step of designing the flip-flop such as to include removable transistors in the flip-flop, and said step c) includes a step of removing the removable transistors to adjust timing if there is a need to reduce a delay.

8. The method as claimed in claim 1, wherein said step a) includes a step of laying out the backup transistors in a close proximity of input/output nodes of the flip-flop.
